(19) United States
(12) Patent Application Publication
(10) Pub. No.: US 2025/0359418 A1
(43) Pub. Date: Nov. 20, 2025

(54) DISPLAY DEVICE AND ELECTRONIC DEVICE INCLUDING THE SAME

(71) Applicant: Samsung Display Co., LTD., Yongin-si (KR)

(72) Inventors: Gi Na YOO, Yongin-si (KR); Hyo Min KIM, Yongin-si (KR); Ji Young KIM, Yongin-si (KR); Eun Ji PARK, Yongin-si (KR)

(21) Appl. No.: 19/009,174

(22) Filed: Jan. 3, 2025

(30) Foreign Application Priority Data
May 16, 2024 (KR) 10-2024-0063667

(51) Int. Cl. H10H 29/855; H10H 29/852

(52) U.S. Cl. CPC H10H 29/8552; H10H 29/852

(57) ABSTRACT

A display device includes: a substrate including a first narrow pixel and a first wide pixel; a first electrode on the substrate; a light emitting layer on the first electrode; a second electrode on the light emitting layer; an encapsulation layer on the second electrode; and a capping layer between the second electrode and the encapsulation layer, where a thickness of the capping layer of the first narrow pixel is greater than a thickness of the capping layer of the first wide pixel.

This application claims priority to Korean Patent Application No. 10-2024-0063667, filed on May 16, 2024, and all the benefits accruing therefrom under 35 U.S.C. § 119, the content of which in its entirety is herein incorporated by reference.

### BACKGROUND

### (1) Field

Embodiments of the disclosure relate to a display device and an electronic device including the same.

### (2) Description of the Related Art

Recently, as interest in an information display is increasing research and development for display devices are continuously conducted.

### SUMMARY

Embodiments of the disclosure relate to a display device with improved reliability by improving power consumption and minimizing degradation in a private mode.

Embodiments of the disclosure is not limited to the embodiment mentioned above, and other technical objects that are not mentioned may be clearly understood to a person of an ordinary skill in the art using the following description.

An embodiment provides a display device including: a substrate including a first narrow pixel and a first wide pixel; a first electrode on the substrate; a light emitting layer on the first electrode; a second electrode on the light emitting layer; an encapsulation layer on the second electrode; and a capping layer between the second electrode and the encapsulation layer, where a thickness of the capping layer of the first narrow pixel is greater than a thickness of the capping layer of the first wide pixel.

In an embodiment, each of the first narrow pixel and the first wide pixel may emit light of a first color.

In an embodiment, the first wide pixel may emit light in a normal mode, and the first narrow pixel may emit light in a private mode.

In an embodiment, a thickness of the light emitting layer of the first narrow pixel may be less than a thickness of the light emitting layer of the first wide pixel.

In an embodiment, the substrate may further include a second narrow pixel and a second wide pixel, and a thickness of the capping layer of the second narrow pixel may be the same as a thickness of the capping layer of the second wide pixel.

In an embodiment, each of the second narrow pixel and the second wide pixel may emit light of a second color.

In an embodiment, a thickness of the capping layer of the first narrow pixel may be greater than a thickness of the capping layer of the second narrow pixel.

In an embodiment, the substrate may further include a third narrow pixel and a third wide pixel, and a thickness of the capping layer of the third narrow pixel may be the same as a thickness of the capping layer of the third wide pixel.

In an embodiment, each of the third narrow pixel and the third wide pixel may emit light of a third color.

In an embodiment, a thickness of the capping layer of the first narrow pixel may be greater than a thickness of the capping layer of the third narrow pixel.

In an embodiment, the substrate may further include a second narrow pixel and a second wide pixel, and a thickness of the capping layer of the second narrow pixel may be greater than a thickness of the capping layer of the second wide pixel.

In an embodiment, a thickness of the capping layer of the first narrow pixel may be the same as a thickness of the capping layer of the second narrow pixel.

In an embodiment, a thickness of the capping layer of the first narrow pixel may be greater than a thickness of the capping layer of the second narrow pixel.

In an embodiment, the display device may further include a first light blocking layer on the encapsulation layer.

In an embodiment, the first light blocking layer may include a first opening overlapping the first narrow pixel and a second opening overlapping the first wide pixel.

In an embodiment, a width of the first opening in the first direction may be less than a width of the second opening in a first direction.

In an embodiment, the display device may further include a second light blocking layer on the first light blocking layer.

In an embodiment, the display device may further include a third light blocking layer on the second light blocking layer.

In an embodiment, the first to third light blocking layers may overlap each other.

In an embodiment, the display device may further include a polarizing layer on the second light blocking layer.

An embodiment provides an electronic device including: a processor to provide input image data; and a display device to display an image based on the input image data, the display device including sub-pixel areas, wherein the display device comprises a substrate including a first narrow pixel and a first wide pixel; a first electrode on the substrate; a light emitting layer on the first electrode; a second electrode on the light emitting layer; an encapsulation layer on the second electrode; and a capping layer between the second electrode and the encapsulation layer, where a thickness of the capping layer of the first narrow pixel is greater than a thickness of the capping layer of the first wide pixel.

According to embodiments of the disclosure, by adjusting the thickness of the capping layer, the light efficiency of narrow pixels may be improved, power consumption in private mode may be improved, and degradation may be minimized to improve reliability.

Effects of embodiments of the disclosure are not limited by what is illustrated in the above, and more various effects are included in the specification.

### BRIEF DESCRIPTION OF THE DRAWINGS

FIG. 1 illustrates a block diagram of a display device according to an embodiment.

FIG. 2 illustrates a block diagram of a sub-pixel according to an embodiment.

FIG. 3 illustrates a circuit diagram of a sub-pixel according to an embodiment.

FIG. 4 illustrates a top plan view of a display panel of FIG. 1 according to an embodiment.

FIG. 5 illustrates a top plan view of a pixel of FIG. 4 according to an embodiment.

FIG. 6 to FIG. 9 illustrate cross-sectional views taken along lines A-A′, B-B′, and C-C′ of FIG. 5 according to various embodiments.

FIG. 10 illustrates a perspective view of an embodiment of a display device.

FIG. 11 to FIG. 15 illustrate cross-sectional views showing processes of a manufacturing method of a display device according to an embodiment.

FIG. 16 is a schematic block diagram illustrating an electronic device including a display device in accordance with an embodiment.

FIG. 17 is a schematic diagram illustrating an example where the electronic device of FIG. 16 is a smartphone.

FIG. 18 is a schematic diagram illustrating an example where the electronic device of FIG. 16 is a tablet computer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Throughout the specification, when it is described that an element is “connected” to another element, this includes not only being “directly connected”, but also being “indirectly connected” with another device in between. It will be understood that when an element is referred to as being “on” another element, it can be directly on the other element or intervening elements may be present therebetween. In contrast, when an element is referred to as being “directly on” another element, there are no intervening elements present.

The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. For the purposes of this disclosure, “at least one of X, Y, and Z” and “at least one selected from X, Y, and Z” may be construed as X only, Y only, Z only, or any combination of two or more of X, Y, and Z, such as, for instance, XYZ, XYY, YZ, and ZZ. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

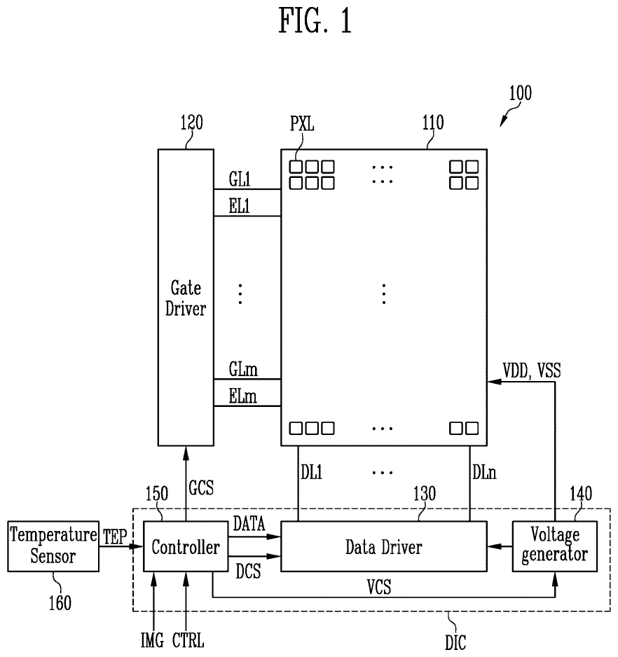

FIG. 1 illustrates a block diagram of a display device according to an embodiment.

Referring to FIG. 1, an embodiment of a display device 100 may include a display panel 110, a gate driver 120, a data driver 130, a voltage generator 140, and a controller 150.

The display panel 110 may include pixels PXL. The pixels PXL may be connected to the gate driver 120 through first to m-th gate lines GL1 to GLm. The pixels PXL may be connected to the data driver 130 through first to n-th data lines DL1 to DLn. Here, m and n are natural numbers greater than 1.

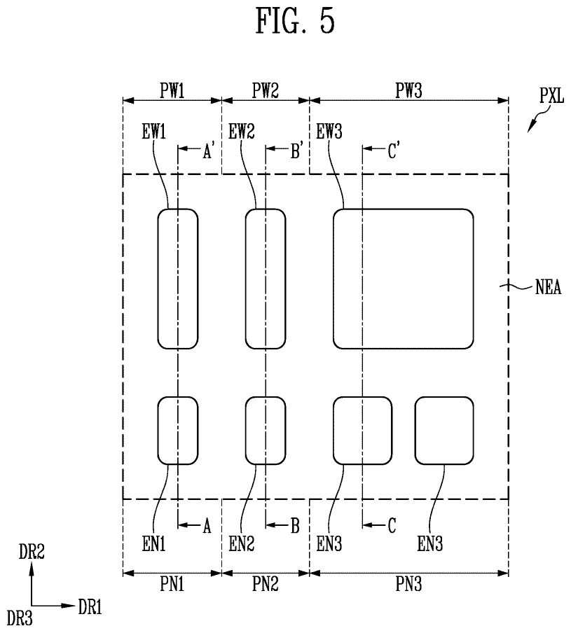

The pixel PXL may include or be configured of a plurality of sub-pixels. Each of the sub-pixels may include at least one light emitting element configured to generate light. Accordingly, the sub-pixels may respectively generate light of a specific color, such as red, green, blue, cyan, magenta, yellow, or the like. In an embodiment, the display panel 110 may be a switchable privacy display panel capable of switching between a normal mode and a private mode with a limited viewing angle. As described above, when the display panel 110 supports the private mode, the sub-pixels may include wide pixels that emit light in the normal mode and narrow pixels that emit light in the private mode. This will be described in detail later with reference to FIG. 5.

The gate driver 120 may be connected to the sub-pixels arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating the start of each frame, a horizontal synchronization signal for outputting gate signals in synchronization with the timing at which data signals are applied, and the like.

In an embodiment, first to m-th light emitting control lines EL1 to ELm connected to the sub-pixels in a row direction may be further provided. In this case, the gate driver 120 may include a light emitting control driver configured to control the first to m-th light emitting control lines EL1 to ELm, and the light emitting control driver may operate under the control of the controller 150.

In an embodiment, the gate driver 120 may be disposed on one side of the display panel 110. However, embodiments are not limited thereto. In another embodiment, for example, the gate driver 120 may be divided into two or more physically and/or logically separated drivers, and the drivers may be disposed on one side of the display panel 110 and the other side of the display panel 110 opposite to the one side. As described above, the gate driver 120 may be disposed around the display panel 110 in various forms according to embodiments.

The data driver 130 may be connected to the sub-pixels arranged in a column direction through the first to n-th data lines DL1 to DLn. The data driver 130 receives image data DATA and data control signal DCS from the controller 150. The data driver 130 operates in response to the data control signal DCS. In an embodiment, the data control signal DCS may include a source start pulse, a source shift clock, a source output enable signal, or the like.

The data driver 130 may use voltages from the voltage generator 140 to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels may generate light corresponding to the data signals. Accordingly, an image is displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device 100. In an embodiment, for example, the voltage generator 140 may be configured to generate a plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels. The first power voltage VDD may have a relatively high voltage level, and the second power voltage VSS may have a voltage level lower than the first power voltage VDD. In another embodiment, the first power voltage VDD or the second power voltage VSS may be provided by an external device of the display device 100.

In an embodiment, the voltage generator 140 may further generate various voltages. In an embodiment, for example, the voltage generator 140 may generate an initialization voltage applied to the sub-pixels. In an embodiment, for example, during a sensing operation to sense electrical characteristics of transistors and/or light emitting elements of the sub-pixels, a predetermined reference voltage may be applied to the first to n-th data lines DL1 to DLn, and the voltage generator 140 may generate the reference voltage.

The controller 150 controls various operations of the display device 100. The controller 150 may receive input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In an embodiment, the controller 150 may output the image data DATA by aligning the input image data IMG to be suitable for the sub-pixels of a row unit.

Two or more components of the data driver 130, the voltage generator 140, and the controller 150 may be defined by one integrated circuit. In an embodiment, as shown in FIG. 1, the data driver 130, the voltage generator 140, and the controller 150 may be included in a driver integrated circuit DIC. In such an embodiment, the data driver 130, the voltage generator 140, and the controller 150 may be functionally separate components within one driver integrated circuit DIC. In another embodiment, at least one selected from the data driver 130, the voltage generator 140, and the controller 150 may be provided as a component separated from the driver integrated circuit DIC.

The display device 100 may include at least one temperature sensor 160. The temperature sensor 160 may be configured to sense a surrounding temperature and generate temperature data TEP representing the sensed temperature. In an embodiment, the temperature sensor 160 may be disposed to be adjacent to the display panel 110 and/or the driver integrated circuit DIC.

The controller 150 may control various operations of the display device 100 in response to the temperature data TEP. In an embodiment, the controller 150 may adjust the luminance of an image outputted from the display panel 110 in response to the temperature data TEP. In an embodiment, for example, the controller 150 may control the data signals and the first and second power voltages VDD and VSS by controlling components such as the data driver 130 and/or the voltage generator 140.

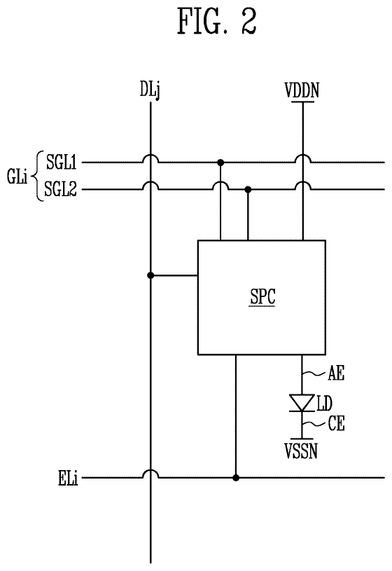

FIG. 2 illustrates a block diagram of a sub-pixel according to an embodiment.

In FIG. 2, an embodiment of a sub-pixel disposed in an i-th row (i is an integer greater than or equal to 1 and less than or equal to m) and a j-th column (j is an integer greater than or equal to 1 and less than or equal to n) is illustrated as an example.

Referring to FIG. 2, an embodiment of the sub-pixel may include a pixel circuit SPC and a light emitting element LD. The light emitting element LD may be connected between a first power voltage node VDDN and a second power voltage node VSSN. In such an embodiment, the first power voltage node VDDN is a node to which the first power voltage VDD of FIG. 1 is transmitted, and the second power voltage node VSSN is a node to which the second power voltage VSS of FIG. 1 is transmitted.

An anode electrode AE of the light emitting element LD may be connected to the first power voltage node VDDN through the pixel circuit SPC, and a cathode electrode CE of the light emitting element LD may be connected to the second power voltage node VSSN. In an embodiment, for example, the anode electrode AE of the light emitting element LD may be connected to the first power voltage node VDDN through one or more transistors included in the pixel circuit SPC.

The pixel circuit SPC may be connected to an i-th gate line GLi among the first to m-th gate lines GL1 to GLm of FIG. 1, an i-th light emitting control line ELi among the first to m-th light emitting control lines EL1 to ELm of FIG. 1, and a j-th data line DLj among the first to n-th data lines DL1 to DLn of FIG. 1. The pixel circuit SPC may be configured to control the light emitting element LD based on signals applied thereto through such signal lines.

The pixel circuit SPC may operate in response to a gate signal received through the i-th gate line GLi. The i-th gate line GLi may include one or more sub-gate lines. In an embodiment, as shown in FIG. 2, the i-th gate line GLi may include first and second sub-gate lines SGL1 and SGL2. The pixel circuit SPC may operate in response to gate signals received through the first and second sub-gate lines SGL1 and SGL2. In such an embodiment, where the i-th gate line GLi includes two or more sub-gate lines, the pixel circuit SPC may operate in response to gate signals received through the corresponding sub-gate lines.

The pixel circuit SPC may operate in response to a light emitting control signal applied thereto through the i-th light emitting control line ELi. In an embodiment, the i-th light emitting control line ELi may include one or more sub-light emitting control lines. In an embodiment where the i-th light emitting control line ELi includes two or more sub-light emitting control lines, the pixel circuit SPC may operate in response to light emitting control signals applied thereto through the corresponding sub-light emitting control lines.

The pixel circuit SPC may receive a data signal through the j-th data line DLj. The pixel circuit SPC may store a voltage corresponding to the data signal in response to at least one of the gate signals applied thereto through the first and second sub-gate lines SGL1 and SGL2. In response to the light emitting control signal received through the i-th light emitting control line ELi, the pixel circuit SPC may adjust the current flowing from the first power voltage node VDDN to the second power voltage node VSSN through the light emitting element LD based on the stored voltage. Accordingly, the light emitting element LD may generate light of luminance corresponding to the data signal.

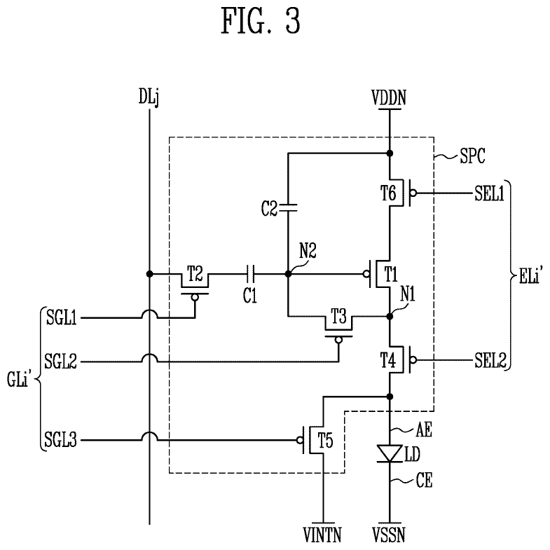

FIG. 3 illustrates a circuit diagram of a sub-pixel according to an embodiment.

Referring to FIG. 3, an embodiment of the sub-pixel may include a pixel circuit SPC and a light emitting element LD.

The pixel circuit SPC may be connected to an i-th gate line GLi′, an i-th light emitting control line ELi′, and a j-th data line DLj. In an embodiment, as shown in FIG. 3, the i-th gate line GLi′ may include the first and second sub-gate lines SGL1 and SGL2, which are described above with reference to FIG. 2, and a third sub-gate line SGL3. In an embodiment, as shown in FIG. 3, the i-th light emitting control line ELi′ may include a first sub-light emitting control line SEL1 and a second sub-light emitting control line SEL2.

In an embodiment, the pixel circuit SPC may include first to sixth transistors T1 to T6, and first and second capacitors C1 and C2.

The first transistor T1 may be connected between the first power voltage node VDDN and a first node N1. A gate of the first transistor T1 is connected to a second node N2, and accordingly, the first transistor T1 may be turned on based on a voltage level of the second node N2. The first transistor T1 may be referred to as a driving transistor.

The second transistor T2 may be connected between the j-th data line DLj and the second node N2. A gate of the second transistor T2 is connected to the first sub-gate line SGL1, and accordingly, the second transistor T2 may be turned on in response to the gate signal of the first sub-gate line SGL1. The second transistor T2 may be referred to as a switching transistor.

The third transistor T3 may be connected between the first node N1 and the second node N2. A gate of the third transistor T3 is connected to the second sub-gate line SGL2, and accordingly, the third transistor T3 may be turned on in response to the gate signal of the second sub-gate line SGL2.

The fourth transistor T4 may be connected between the first node N1 and the anode electrode AE of the light emitting element LD. A gate of the fourth transistor T4 is connected to the second sub-light emitting control line SEL2, and accordingly, the fourth transistor T4 may be turned on in response to the light emitting control signal of the second sub-light emitting control line SEL2.

The fifth transistor T5 may be connected between the anode electrode AE of the light emitting element LD and an initialization voltage node VINTN. The initialization voltage node VINTN may transmit an initialization voltage to the pixel circuit SPC. In an embodiment, the initialization voltage may be provided by the voltage generator 140 of FIG. 1. In another embodiment, the initialization voltage may be provided by an external device to the display device 100. A gate of the fifth transistor T5 is connected to the third sub-gate line SGL3, and accordingly, the fifth transistor T5 may be turned on in response to the gate signal of the third sub-gate line SGL3.

The sixth transistor T6 may be connected between a first power voltage node VDDN and the first transistor T1. A gate of the sixth transistor T6 is connected to the first sub-light emitting control line SEL1, and accordingly, the sixth transistor T6 may be turned on in response to the light emitting control signal of the first sub-light emitting control line SEL1.

The first capacitor C1 may be connected between the second transistor T2 and the second node N2. The second capacitor C2 may be connected between the first power voltage node VDDN and the second node N2.

In an embodiment, as described above, the pixel circuit SPC may include the first to sixth transistors T1 to T6 and the first and second capacitors C1 and C2. However, embodiments are not limited thereto. The pixel circuit SPC may be implemented as one of various circuits including a plurality of transistors and one or more capacitors. In an embodiment, for example, the pixel circuit SPC may include two transistors and one capacitor. According to embodiments of the pixel circuit SPC, the number of sub-gate lines included in the i-th gate line GLi′ and the number of sub-light emitting control lines included in the i-th light emitting control line ELi′ may be changed or variously modified.

In an embodiment, the first to sixth transistors T1 to T6 may be P-type transistors. Each of the first to sixth transistors T1 to T6 may be a metal oxide silicon field effect transistor (MOSFET). However, embodiments are not limited thereto. In another embodiment, for example, at least one of the first to sixth transistors T1 to T6 may be replaced with an N-type transistor.

In an embodiment, each of the first to sixth transistors T1 to T6 may include at least one selected from an amorphous silicon semiconductor, a monocrystalline silicon semiconductor, a polycrystalline silicon semiconductor, and an oxide semiconductor.

The light emitting element LD may include the anode electrode AE, the cathode electrode CE, and the light emitting layer. The light emitting layer may be disposed between the anode electrode AE and the cathode electrode CE. After the data signal transmitted through the j-th data line DLj is reflected in the voltage of the second node N2, the fourth and sixth transistors T4 and T6 may be turned on when the light emitting control signals of the first and second sub-light emitting control lines SEL1 and SEL2 are enabled to a low level. The first transistor T1 may be turned on based on the voltage of the second node N2, and accordingly, a current may flow from the first power voltage node VDDN to the second power voltage node VSSN. The light emitting element LD may emit light corresponding to a current flowing therethrough.

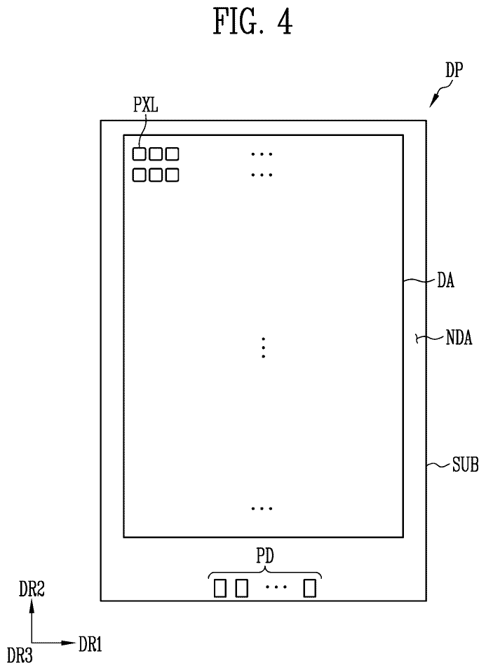

FIG. 4 illustrates a top plan view of a display panel of FIG. 1 according to an embodiment.

Referring to FIG. 4, an embodiment DP of the display panel 110 of FIG. 1 may include a display area DA and a non-display area NDA. The display panel DP displays an image through the display area DA. The non-display area NDA may be disposed around the display area DA, and no image may be displayed through the non-display area NDA.

The display panel DP may include a substrate SUB, pixels PXL, and pads PD. The pixels PXL may be disposed in the display area DA on the substrate SUB, and may not be disposed in the non-display area NDA. The pixels PXL may be arranged in a matrix form along a first direction DR1 and a second direction DR2 that intersects the first direction DR1. However, embodiments are not limited thereto. The first direction DR1 may be a row direction, and the second direction DR2 may be a column direction.

A constituent element to control the pixels PXL may be disposed in the non-display area NDA on the substrate SUB. In an embodiment, for example, wires defining signals lines such as the first to m-th gate lines GL1 to GLm and the first to n-th data lines DL1 to DLn of FIG. 1, may be disposed in the non-display area NDA.

At least one selected from the gate driver 120, the data driver 130, the voltage generator 140, the controller 150, and the temperature sensor 160 in FIG. 1 may be integrated (or integrally formed) in the non-display area NDA of the display panel DP. In an embodiment, the gate driver 120 of FIG. 1 may be mounted on the display panel DP, and may be disposed in the non-display area NDA. In another embodiment, the gate driver 120 may be implemented as an integrated circuit separated from the display panel DP. In an embodiment, the temperature sensor 160 may be disposed in the non-display area NDA to detect the temperature of the display panel DP.

The pads PD may be disposed in the non-display area NDA on the substrate SUB. The pads PD may be electrically connected to the pixels PXL through wires. In an embodiment, for example, the pads PD may be connected to the pixels PXL through the first to n-th data lines DL1 to DLn.

The display panel DP may interface with other constituent elements of the display device 100 (see FIG. 1) through the pads PD. In an embodiment, voltages and signals used for operations of constituent elements included in the display panel DP may be provided from the driver integrated circuit DIC of FIG. 1 through the pads PD. In an embodiment, for example, the first to n-th data lines DL1 to DLn may be connected to the driver integrated circuit DIC through the pads PD. In an embodiment, for example, the first and second power voltages VDD and VSS may be received from the driver integrated circuit DIC through the pads PD. In an embodiment, for example, when the gate driver 120 is mounted on the display panel DP, the gate control signal GCS may be transmitted from the driver integrated circuit DIC to the gate driver 120 through the pads PD.

In an embodiment, the circuit board may be electrically connected to the pads PD by using a conductive adhesive member such as an anisotropic conductive film. In such an embodiment, the circuit board may be a flexible printed circuit board (FPCB) or a flexible film including or made of a flexible material. The driver integrated circuit DIC may be mounted on the circuit board to be electrically connected to the pads PD.

In an embodiment, the display area DA may have various shapes. The display area DA may have a closed-loop shape including sides of a straight line and/or a curved line. In an embodiment, for example, the display area DA may have one of various shapes such as a polygonal shape, a circular shape, a semicircular, and an elliptical shape.

In an embodiment, the display panel DP may have a flat display surface. In another embodiment, the display panel DP may have a display surface that is at least partially round. In an embodiment, the display panel DP may be bendable, foldable, or rollable. In such embodiments, the display panel DP and/or the substrate SUB may include materials with flexible properties.

FIG. 5 illustrates a top plan view of a pixel of FIG. 4 according to an embodiment.

Referring to FIG. 5, the pixel PXL may include wide pixels PW1, PW2, and PW3 and narrow pixels PN1, PN2, and PN3. The wide pixels PW1, PW2, and PW3 may be sub-pixels having a relatively wide viewing angle. The narrow pixels PN1, PN2, and PN3 may be sub-pixels having a viewing angle narrower than that of the wide pixels PW1, PW2, and PW3. The wide pixels PW1, PW2, and PW3 may emit light in the normal mode, and the narrow pixels PN1, PN2, and PN3 may emit light in the private mode. In an embodiment, for example, the wide pixels PW1, PW2, and PW3 may not emit light in the private mode, and the narrow pixels PN1, PN2, and PN3 may not emit light in the normal mode. Accordingly, an image having a normal viewing angle may be displayed in the normal mode, and an image having a relatively limited viewing angle may be displayed in the private mode, such that it is possible to effectively prevent the image from being visually recognized in a specific direction of the display panel DP, for example, from a side, in the private mode. However, the operations of the normal mode and the private mode are not necessarily limited thereto, and in some embodiments, all of the wide pixels PW1, PW2, and PW3 and the narrow pixels PN1, PN2, and PN3 may emit light in the normal mode.

The wide pixels PW1, PW2, and PW3 may include a first wide pixel PW1, a second wide pixel PW2, and a third wide pixel PW3. The first wide pixel PW1, the second wide pixel PW2, and the third wide pixel PW3 may be disposed or arranged in the first direction DR1. The first wide pixel PW1 may include a first wide light emitting area EW1 and a non-light emitting area NEA around the first wide light emitting area EW1. The second wide pixel PW2 may include a second wide light emitting area EW2 and the non-light emitting area NEA around the second wide light emitting area EW2. The third wide pixel PW3 may include a third wide light emitting area EW3 and the non-light emitting area NEA around the third wide light emitting area EW3.

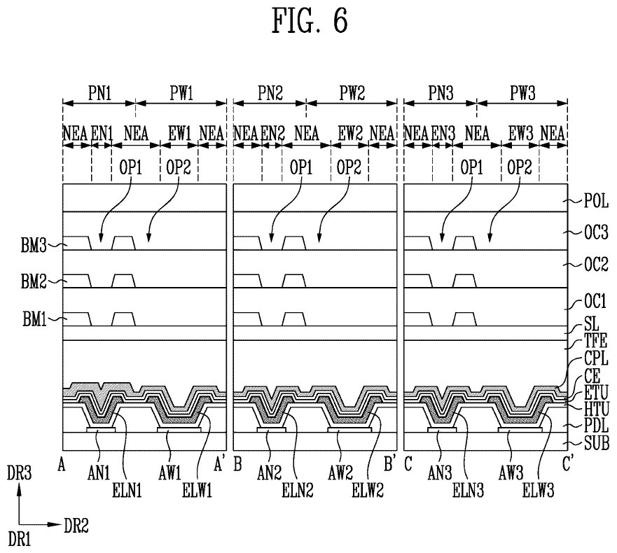

The first wide light emitting area EW1 may be an area in which light is emitted from a first wide light emitting layer ELW1 (see FIG. 6) disposed in the first wide pixel PW1. The second wide light emitting area EW2 may be an area in which light is emitted from a second wide light emitting layer ELW2 (see FIG. 6) disposed in the second wide pixel PW2. The third wide light emitting area EW3 may be an area in which light is emitted from a third wide light emitting layer ELW3 (see FIG. 6) disposed in the third wide pixel PW3.

A size (e.g., a planar area) of the first wide light emitting area EW1 may be the same as that of the second wide light emitting area EW2. A size of the third wide light emitting area EW3 may be larger than that of the first wide light area EW1 and/or that of the second wide light emitting area EW2. However, the sizes and shapes of the first to third wide light emitting areas EW1, EW2, and EW3 are not limited to the embodiment illustrated in FIG. 5, and may be modified to have various sizes and shapes.

The narrow pixels PN1, PN2, and PN3 may include a first narrow pixel PN1, a second narrow pixel PN2, and a third narrow pixel PN3. The first narrow pixel PN1, the second narrow pixel PN2, and the third narrow pixel PN3 may be disposed in the first direction DR1. The first narrow pixel PN1 and the first wide pixel PW1 may be disposed in the second direction DR2. The second narrow pixel PN2 and the second wide pixel PW2 may be disposed in the second direction DR2. The third narrow pixel PN3 and the third wide pixel PW3 may be disposed in the second direction DR2.

The first narrow pixel PN1 may include a first narrow light emitting area EN1 and the non-light emitting area NEA around the first narrow light emitting area EN1. The second narrow pixel PN2 may include a second narrow light emitting area EN2 and the non-light emitting area NEA around the second narrow light emitting area EN2. The third narrow pixel PN3 may include a third narrow light emitting area EN3 and the non-light emitting area NEA around the third narrow light emitting area EN3.

The first narrow light emitting area EN1 may be an area in which light is emitted from a first narrow light emitting layer ELN1 (see FIG. 6) disposed in the first narrow pixel PN1. The second narrow light emitting area EN2 may be an area in which light is emitted from a second narrow light emitting layer ELN2 (see FIG. 6) disposed in the second narrow pixel PN2. The third narrow light emitting area EN3 may be an area in which light is emitted from a third narrow light emitting layer ELN3 (see FIG. 6) disposed in the third narrow pixel PN3.

A size of the first narrow light emitting area EN1 may be the same as that of the second narrow light emitting area EN2. The third narrow pixel PN3 may include two third narrow light emitting areas EN3 spaced apart from each other. The size of each of the third narrow light emitting areas EN3 may be greater than that of the first narrow light emitting area EN1 and/or that of the second narrow light emitting area EN2. However, the sizes and shapes of the first to third narrow light emitting areas EN1, EN2, and EN3 are not limited to the embodiment illustrated in FIG. 5, and may be modified to have various sizes and shapes.

The size of the first narrow light emitting area EN1 may be smaller than that of the first wide light emitting area EW1. The size of the second narrow light emitting area EN2 may be smaller than that of the second wide light emitting area EW2. The size of the third narrow light emitting area EN3 may be smaller than that of the third wide light emitting area EW3. As described above, by forming the narrow light emitting areas EN1, EN2, and EN3 to be relatively small, the viewing angle of the image being viewed from the side may be limited, thereby implementing the private mode.

FIG. 6 to FIG. 9 illustrate cross-sectional views taken along lines A-A′, B-B′, and C-C′ of FIG. 5 according to various embodiments.

Referring to FIG. 6 to FIG. 9, in embodiments, anode electrodes AW1, AW2, AW3, AN1, AN2, and AN3 may be disposed on the substrate SUB. The substrate SUB may include a base layer and a circuit layer. The base layer may include or be formed of polyimide (PI), glass, or silicon wafer. The circuit layer includes conductive patterns and insulating layers, and the conductive patterns may define or function as the pixel circuit SPC (see FIG. 2) and various wires. The circuit layer may include transistors and one or more capacitors. Each transistor may include a semiconductor portion including a source region, a drain region, and a channel region, and a gate electrode overlapping the semiconductor portion. Each capacitor may include electrodes spaced apart from each other in the third direction DR3 with an insulating layer therebetween. Wires of the circuit layer may include signal lines, for example, a gate line, a light emitting control line, and a data line.

The anode electrodes AW1, AW2, AW3, AN1, AN2, and AN3 may be electrically connected to the circuit layer of the substrate SUB. The anode electrodes AW1, AW2, AW3, AN1, AN2, and AN3 may include an opaque conductive material capable of reflecting light, but embodiments are not limited thereto.

The first to third wide anode electrodes AW1, AW2, and AW3 may be disposed in the first to third wide pixels PW1, PW2, and PW3, respectively. The first to third wide anode electrodes AW1, AW2, and AW3 may have a shape similar to that of the first to third wide light emitting areas EW1, EW2, and EW3 in a plan view or when viewed in the third direction DR3.

The first to third wide anode electrodes AW1, AW2, and AW3 may include at least one selected from transparent conductive materials such as an indium tin oxide (ITO), an indium zinc oxide (IZO), a zinc oxide (ZnOx), an indium gallium zinc oxide (IGZO), and an indium tin zinc oxide (ITZO). However, the materials of the first to third wide anode electrodes AW1, AW2, and AW3 are not limited thereto. In another embodiment, for example, first to third wide anode electrodes AW1, AW2, and AW3 may include titanium nitride.

The first to third narrow anode electrodes AN1, AN2, and AN3 may be disposed in the first to third narrow pixels PN1, PN2, and PN3, respectively. The first to third narrow anode electrodes AN1, AN2, and AN3 may have a shape similar to that of the first to third narrow light emitting areas EN1, EN2, and EN3 in a plan view.

The first to third narrow anode electrodes AN1, AN2, and AN3 may include at least one selected from transparent conductive materials such as an indium tin oxide (ITO), an indium zinc oxide (IZO), a zinc oxide (ZnOx), an indium gallium zinc oxide (IGZO), and an indium tin zinc oxide (ITZO). However, the materials of the first to third narrow anode electrodes AN1, AN2, and AN3 are not limited thereto. In another embodiment, for example, the first to third narrow anode electrodes AN1, AN2, and AN3 may include titanium nitride.

The anode electrodes AW1, AW2, AW3, AN1, AN2, and AN3 may be disposed in (or directly on) a same layer as each other, and may be formed simultaneously in a same process, but are not limited thereto.

A pixel defining film PDL may be disposed on the anode electrodes AW1, AW2, AW3, AN1, AN2, and AN3. The pixel defining film PDL may be disposed in the non-light emitting area NEA. The pixel defining film PDL may define or be provided with openings exposing respective portions of the anode electrodes AW1, AW2, AW3, AN1, AN2, and AN3. The openings of the pixel defining film PDL may define the first to third wide light emitting areas EW1, EW2, and EW3.

Light emitting element layers HTU, ELW1, ELW2, ELW3, ELN1, ELN2, ELN3, and ETU may be disposed on the anode electrodes AW1, AW2, AW3, AN1, AN2, and AN3 and the pixel defining film PDL. The light emitting element layers HTU, ELW1, ELW2, ELW3, ELN1, ELN2, ELN3, and ETU may include a hole transport portion HTU, light emitting layers ELW1, ELW2, ELW3, ELN1, ELN2, and ELN3, and/or an electron transport portion ETU. The light emitting layers ELW1, ELW2, ELW3, ELN1, ELN2, and ELN3 may be disposed between the hole transport portion HTU and the electron transport portion ETU.

The hole transport portion HTU may be disposed on the anode electrodes AW1, AW2, AW3, AN1, AN2, and AN3 and the pixel defining film PDL. The hole transport portion HTU may be entirely disposed on (or commonly disposed over) the wide pixels PW1, PW2, and PW3 and the narrow pixels PN1, PN2, and PN3. The hole transport portion HTU may include at least one selected from a hole injection layer and a hole transport layer, and may further include a hole buffer layer, an electron blocking layer, or the like, if desired.

The first to third wide light emitting layers ELW1, ELW2, and ELW3 may be disposed in the first to third wide pixels PW1, PW2, and PW3, respectively. The first to third wide light emitting layers ELW1, ELW2, and ELW3 may be disposed on the first to third wide anode electrodes AW1, AW2, and AW3, respectively.

The first to third narrow light emitting layers ELN1, ELN2, and ELN3 may be disposed in the first to third narrow pixels PN1, PN2, and PN3, respectively. The first to third narrow light emitting layers ELN1, ELN2, and ELN3 may be disposed on the first to third narrow anode electrodes AN1, AN2, and AN3, respectively.

The first wide light emitting layer ELW1 and the first narrow light emitting layer ELN1 may be disposed in (or directly on) a same layer as each other and may be formed simultaneously in a same process, but are not limited thereto. The first wide light emitting layer ELW1 and the first narrow light emitting layer ELN1 may generate light of a first color, for example, a red color.

The second wide light emitting layer ELW2 and the second narrow light emitting layer ELN2 may be disposed in (or directly on) a same layer as each other and may be formed simultaneously in the same process, but are not limited thereto. The second wide light emitting layer ELW2 and the second narrow light emitting layer ELN2 may generate light of a second color, for example, a green color.

The third wide light emitting layer ELW3 and the third narrow light emitting layer ELN3 may be disposed in (or directly on) a same layer as each other and may be formed simultaneously in the same process, but are not limited thereto. The third wide light emitting layer ELW3 and the third narrow light emitting layer ELN3 may generate light of a third color, for example, a blue color.

The electron transport portion ETU may be disposed on the light emitting layers ELW1, ELW2, ELW3, ELN1, ELN2, and ELN3. The electron transport portion ETU may be entirely disposed on (or commonly disposed over) the wide pixels PW1, PW2, and PW3 and the narrow pixels PN1, PN2, and PN3. The electron transport portion ETU may include at least one selected from an electron injection layer and an electron transport layer, and may further include an electron buffer layer, a hole blocking layer, or the like, if desired.

A cathode electrode CE may be disposed on the light emitting element layers HTU, ELW1, ELW2, ELW3, ELN1, ELN2, ELN3, and ETU. The cathode electrode CE may be entirely disposed on the wide pixels PW1, PW2, and PW3 and the narrow pixels PN1, PN2, and PN3. The cathode electrode CE may function as a half mirror that partially transmits and partially reflects light emitted from the light emitting element layers HTU, ELW1, ELW2, ELW3, ELN1, ELN2, ELN3, and ETU. In an embodiment, for example, the cathode electrode CE may include or be made of a metallic material or a transparent conductive material to have a relatively thin thickness. In an embodiment, the cathode electrode CE may include at least one selected from various transparent conductive materials including an indium tin oxide, an indium zinc oxide, an indium tin zinc oxide, an aluminum zinc oxide, a gallium zinc oxide, a zinc tin oxide, and a gallium tin oxide. In another embodiment, the cathode electrode CE may include at least one selected from silver (Ag), magnesium (Mg), and a mixture thereof. However, the material of the cathode electrode CE is not limited thereto.

The first wide anode electrode AW1, the portion of the light emitting element layers HTU, ELW1, and ETU overlapping the first wide anode electrode AW1, and the portion of the cathode electrode CE overlapping the first wide anode electrode AW1 may configure (or collectively define) a first wide light emitting element. The second wide anode electrode AW2, the portion of the light emitting element layers HTU, ELW2, and ETU overlapping the second wide anode electrode AW2, and the portion of the cathode electrode CE overlapping the second wide anode electrode AW2 may configure (or collectively define) a second wide light emitting element. The third wide anode electrode AW3, the portion of the light emitting element layers HTU, ELW3, and ETU overlapping the third wide anode electrode AW3, and the portion of the cathode electrode CE overlapping the third wide anode electrode AW3 may configure (or collectively define) a third wide light emitting element.

The first narrow anode electrode AN1, the portion of the light emitting element layers HTU, ELN1, and ETU overlapping the first narrow anode electrode AN1, and the portion of the cathode electrode CE overlapping the first narrow anode electrode AN1 may configure (or collectively define) a first narrow light emitting element. The second narrow anode electrode AN2, the portion of the light emitting element layers HTU, ELN2, and ETU overlapping the second narrow anode electrode AN2, and the portion of the cathode electrode CE overlapping the second narrow anode electrode AN2 may configure (or collectively define) a second narrow light emitting element. The third narrow anode electrode AN3, the portion of the light emitting element layers HTU, ELN3, and ETU overlapping the third narrow anode electrode AN3, and the portion of the cathode electrode CE overlapping the third narrow anode electrode AN3 may configure (or collectively define) a third narrow light emitting element.

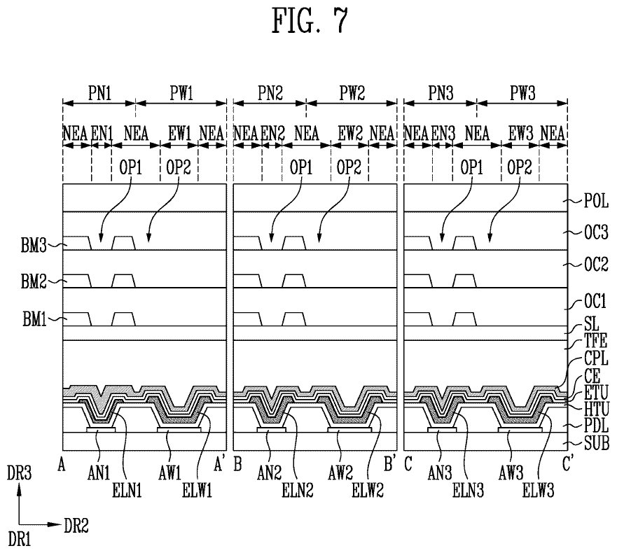

A capping layer CPL may be disposed on the cathode electrode CE. The capping layer CPL may cover the cathode electrode CE to effectively prevent oxidation of the cathode electrode CE. The capping layer CPL may be formed as an inorganic film (or an inorganic insulating film) including an inorganic material. In an embodiment, the capping layer CPL may serve to improve light efficiency by resonance. Accordingly, the light efficiency of the narrow pixels PN1, PN2, and PN3 may be improved by adjusting the thickness of the capping layer CPL of the narrow pixels PN1, PN2, and PN3 in which the light emitting areas are formed relatively small. In an embodiment, for example, as illustrated in FIG. 6, the thickness of the capping layer CPL of the first narrow pixel PN1 in the third direction DR3 may be greater than the thickness of the capping layer CPL of the first wide pixel PW1 in the third direction DR3. The thickness of the capping layer CPL of the first narrow pixel PN1 in the third direction DR3 may be greater than the thickness of the capping layer CPL of the second narrow pixel PN2 in the third direction DR3 and/or that of the capping layer CPL of the third narrow pixel PN3 in the third direction DR3. The thickness of the capping layer CPL of the second narrow pixel PN2 in the third direction DR3 may be the same as the thickness of the capping layer CPL of the second wide pixel PW2 in the third direction DR3. The thickness of the capping layer CPL of the third narrow pixel PN3 in the third direction DR3 may be the same as the thickness of the capping layer CPL of the third wide pixel PW3 in the third direction DR3. By adjusting the thickness of the capping layer CPL in the above-described manner, the light efficiency of the narrow pixels PN1, PN2, and PN3 may be improved. Accordingly, in an embodiment, where the sizes of the light emitting areas of the narrow pixels PN1, PN2, and PN3 are formed relatively small to implement the private mode, the private mode having a same luminance level as the normal mode may be implemented by adjusting the thickness of the capping layer CPL. Accordingly, it is possible to improve the reliability of the display device by improving the power consumption of the private mode and minimizing degradation. In some embodiments, as illustrated in FIG. 7, the thickness of the first narrow light emitting layer ELN1 in the third direction DR3 may be less than the thickness of the first wide light emitting layer ELW1 in the third direction DR3. The thickness of the first narrow light emitting layer ELN1 in the third direction DR3 may be less than the thickness of the second narrow light emitting layer ELN2 in the third direction DR3 and/or that of the third narrow light emitting layer ELN3 in the third direction DR3. The thickness of the second narrow light emitting layer ELN2 in the third direction DR3 may be the same as the thickness of the second wide light emitting layer ELW2 in the third direction DR3. The thickness of the third narrow light emitting layer ELN3 in the third direction DR3 may be the same as the thickness of the third wide light emitting layer ELW3 in the third direction DR3. As described above, in an embodiment where the capping layer CPL of the first narrow pixel PN1 is formed relatively thick, the thickness of the first narrow light emitting layer ELN1 is formed relatively thin such that the difference in color coordinates between pixels may be minimized.

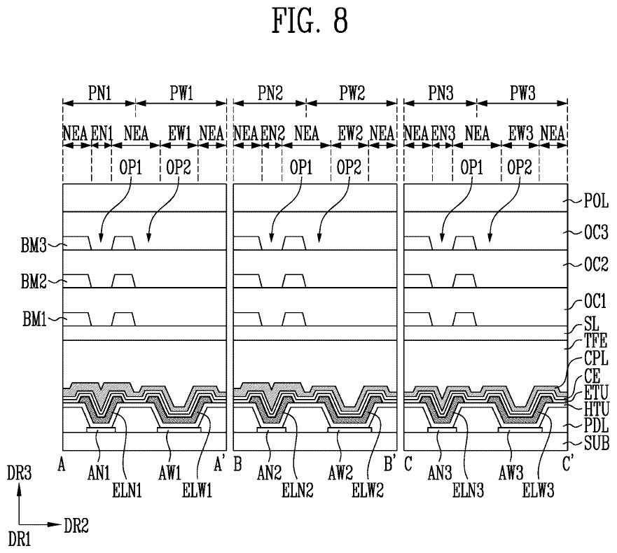

Alternatively, as illustrated in FIG. 8, the thickness of the capping layer CPL of the first narrow pixel PN1 in the third direction DR3 may be greater than the thickness of the capping layer CPL of the first wide pixel PW1 in the third direction DR3. The thickness of the capping layer CPL of the second narrow pixel PN2 in the third direction DR3 may be greater than the thickness of the capping layer CPL of the second wide pixel PW2 in the third direction DR3. The thickness of the capping layer CPL of the first narrow pixel PN1 in the third direction DR3 may be the same as the thickness of the capping layer CPL of the second narrow pixel PN2 in the third direction DR3. The thickness of the capping layer CPL of the first narrow pixel PN1 in the third direction DR3 and/or the thickness of the capping layer CPL of the second narrow pixel PN2 in the third direction DR3 may be greater than the thickness of the capping layer CPL of the third narrow pixel PN3 in the third direction DR3. The thickness of the capping layer CPL of the third narrow pixel PN3 in the third direction DR3 may be the same as the thickness of the capping layer CPL of the third wide pixel PW3 in the third direction DR3. As described above, by adjusting the thickness of the capping layer CPL, the light efficiency of the narrow pixels PN1, PN2, and PN3 may be improved, power consumption in the private mode may be improved, and degradation may be minimized to improve reliability.

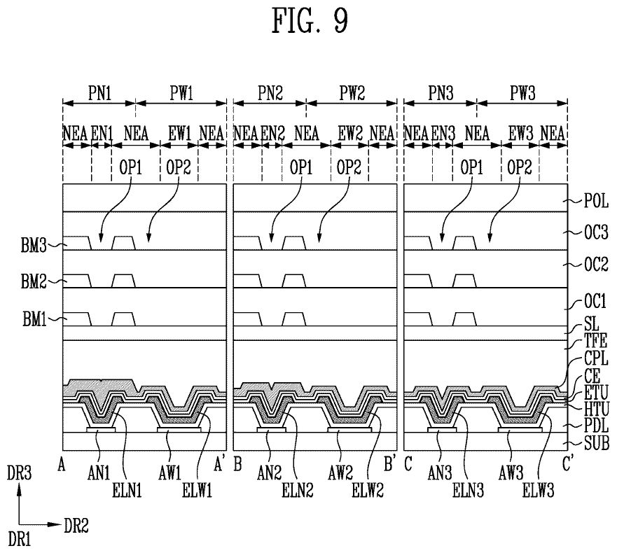

Alternatively, as illustrated in FIG. 9, the thickness of the capping layer CPL of the first narrow pixel PN1 in the third direction DR3 may be greater than the thickness of the capping layer CPL of the first wide pixel PW1 in the third direction DR3. The thickness of the capping layer CPL of the first narrow pixel PN1 in the third direction DR3 may be greater than the thickness of the capping layer CPL of the second narrow pixel PN2 in the third direction DR3 and/or the thickness of the capping layer CPL of the third narrow pixel PN3 in the third direction DR3. The thickness of the capping layer CPL of the second narrow pixel PN2 in the third direction DR3 may be greater than the thickness of the capping layer CPL of the second wide pixel PW2 in the third direction DR3. The thickness of the capping layer CPL of the third narrow pixel PN3 in the third direction DR3 may be the same as the thickness of the capping layer CPL of the third wide pixel PW3 in the third direction DR3. As described above, by adjusting the thickness of the capping layer CPL, the light efficiency of the narrow pixels PN1, PN2, and PN3 may be improved, power consumption in the private mode may be improved, and degradation may be minimized to improve reliability. However, the thickness of the capping layer CPL is not limited to those of the embodiments illustrated in FIG. 6 to FIG. 9, and may be variously changed in consideration of the resonance frequency and transmittance for each wavelength.

An encapsulation layer TFE may be disposed on the capping layer CPL. The encapsulation layer TFE may prevent oxygen and/or moisture from penetrating into the light emitting element layer. The encapsulation layer TFE may include a structure in which one or more inorganic films and one or more organic films are alternately stacked one on another. In an embodiment, for example, the inorganic film may include a silicon nitride, a silicon oxide, or a silicon oxynitride (SiOxNy). In an embodiment, for example, the organic film may include an organic insulating material such as an acrylic resin, an epoxy resin, a phenol resin, a polyamide resin, a polyimide resin, an unsaturated polyesters resin, a polyphenylenethers resin, a polyphenylenesulfides resin, or a benzocyclobutene. However, the materials of the organic film and the inorganic film of the encapsulation layer TFE are not limited thereto.

A sensing layer SL may be disposed on the encapsulation layer TFE. The sensing layer SL may receive a user's touch input. The sensing layer SL may recognize a touch event of the display panel DP through a user's hand or a separate input member. In an embodiment, for example, the sensing layer SL may recognize a touch event using a capacitive method, but is not limited thereto. In an embodiment, the sensing layer SL may include a first sensing conductive layer, a second sensing conductive layer, and an insulating layer between the first sensing conductive layer and the second sensing conductive layer. The first sensing conductive layer and the second sensing conductive layer may configure sensing electrodes of the sensing layer SL. However, the structure of the sensing layer SL is not necessarily limited thereto, and may be variously changed according to embodiments.

Light blocking layers BM1, BM2, and BM3 may be disposed on the sensing layer SL. The light blocking layers BM1, BM2, and BM3 may be provided with first openings OP1 overlapping the narrow pixels PN1, PN2, and PN3 in the third direction DR3, and second openings OP2 overlapping the wide pixels PW1, PW2, and PW3 in the third direction DR3, respectively. The first openings OP1 of the light blocking layers BM1, BM2, and BM3 may define the narrow light emitting areas EN1, EN2, and EN3. The width of the first opening OP1 of the light blocking layers BM1, BM2, and BM3 in the second direction DR2 may be less than the width of the second opening OP2 in the second direction DR2. As described above, by forming the first openings OP1 of the light blocking layers BM1, BM2, and BM3 to be relatively small, the viewing angle of the narrow pixels PN1, PN2, and PN3 is limited to minimize the image being viewed from a side, thereby implementing the private mode.

The first light blocking layer BM1 may be disposed on the sensing layer SL. The second light blocking layer BM2 may be disposed on the first light blocking layer BM1. The third light blocking layer BM3 may be disposed on the second light blocking layer BM2. The first to third light blocking layers BM1, BM2, and BM3 may overlap each other in the third direction DR3.

A first overcoat layer OC1 may be disposed between the first light blocking layer BM1 and the second light blocking layer BM2. A second overcoat layer OC2 may be disposed between the second light blocking layer BM2 and the third light blocking layer BM3. A third overcoat layer OC3 may be disposed on the third light blocking layer BM3. Each of the first to third overcoat layers OC1, OC2, and OC3 may include at least one selected from various materials suitable for protecting lower layers thereof from dust, moisture, or the like. In an embodiment, for example, each of the first to third overcoat layers OC1, OC2, and OC3 may include at least one selected from an inorganic insulating film and an organic insulating film. In an embodiment, for example, the first to third overcoat layers OC1, OC2, and OC3 may include epoxy, but are not limited thereto.

A polarizing layer POL may be disposed on the third overcoat layer OC3. The polarizing layer POL may serve to effectively prevent reflection of external light. In some embodiments, the polarizing layer POL may be omitted.

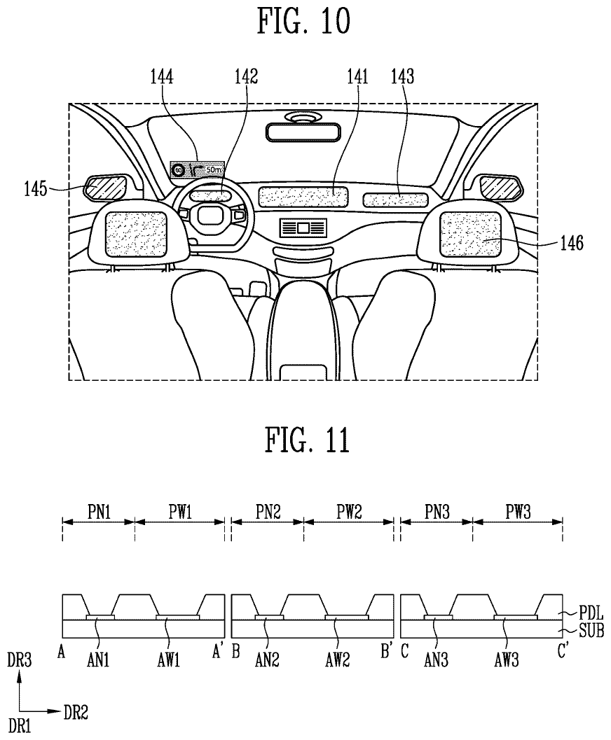

FIG. 10 illustrates a perspective view of an application example of a display device.

Referring to FIG. 10, the display device according to an embodiment may be applied to an automotive display. For example, the automotive display may mean an electronic device that is provided inside and outside a vehicle to provide image data.

In an embodiment, for example, the display device may be applied to at least one selected from an infotainment panel 141, a cluster 142, a co-driver display 143, a head-up display 144, a side mirror display 145, and a rear-seat display 146, which are provided in the vehicle. In an embodiment, for example, the display device may be applied to the co-driver display 143 to be switched to a private mode while driving. In such an embodiment, since the co-driver display 143 may not be visible from the driver's seat, even if the passenger in the passenger seat uses the display while driving, the driver's gaze can be prevented from being distracted. However, the automatic display is not limited to the embodiment shown in FIG. 10, and the infotainment panel 141, the cluster 142, and/or the co-driver display 143 may be integrally formed as one display, and the driver's seat area may be implemented in the normal mode and the passenger seat area may be implemented to enable switching between the normal mode and the private mode.

Hereinafter, an embodiment of a manufacturing method of the display device according to the above-described embodiment will be described.

FIG. 11 to FIG. 15 illustrate cross-sectional views showing processes of a manufacturing method of a display device according to an embodiment. FIG. 11 to FIG. 15 are cross-sectional views for explaining a manufacturing method of the display device of FIG. 1 to FIG. 6, and are briefly shown for better understanding and ease of description, and detailed symbols therein are omitted.

Referring to FIG. 11, first, the anode electrodes AW1, AW2, AW3, AN1, AN2, and AN3 and the pixel defining film PDL are provided or formed on the substrate SUB. The first to third narrow anode electrodes AN1, AN2, and AN3 may be provided or formed in the first to third narrow pixels PN1, PN2, and PN3, respectively. The first to third wide anode electrodes AW1, AW2, and AW3 may be provided or formed in the first to third wide pixels PW1, PW2, and PW3, respectively. The anode electrodes AW1, AW2, AW3, AN1, AN2, and AN3 may be formed simultaneously in a same process, but are not limited thereto.

The pixel defining film PDL may be provided or formed on the anode electrodes AW1, AW2, AW3, AN1, AN2, and AN3. Openings exposing respective portions of the anode electrodes AW1, AW2, AW3, AN1, AN2, and AN3 may be formed through the pixel defining film PDL.

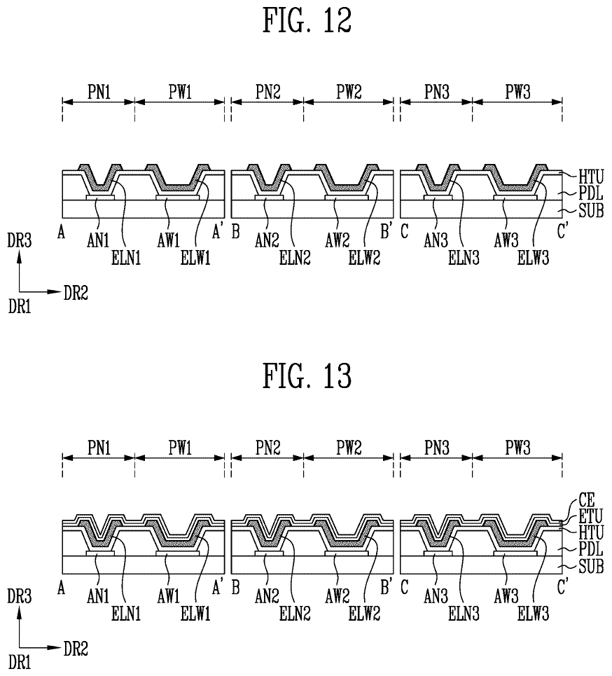

Referring to FIG. 12, then, the hole transport portion HTU and the light emitting layers ELW1, ELW2, AW3, AN1, AN2, and ELN3 are provided or formed on the anode electrodes AW1, AW2, AW3, ELW3, ELN1, ELN2, and ELN3 and the pixel defining film PDL. The hole transport portion HTU may be entirely formed on the wide pixels PW1, PW2, and PW3 and the narrow pixels PN1, PN2, and PN3.

The first to third wide light emitting layers ELW1, ELW2, and ELW3 may be provided or formed in the first to third wide pixels PW1, PW2, and PW3, respectively. The first to third wide light emitting layers ELW1, ELW2, and ELW3 may be formed on the first to third wide anode electrodes AW1, AW2, and AW3, respectively.

The first to third narrow light emitting layers ELN1, ELN2, and ELN3 may be provided or formed in the first to third narrow pixels PN1, PN2, and PN3, respectively. The first to third narrow light emitting layers ELN1, ELN2, and ELN3 may be formed on the first to third narrow anode electrodes AN1, AN2, and AN3, respectively.

The first wide light emitting layer ELW1 and the first narrow light emitting layer ELN1 may be formed directly on a same layer and may be formed simultaneously in a same process, but are not limited thereto. The second wide light emitting layer ELW2 and the second narrow light emitting layer ELN2 may be formed directly on a same layer as each other and may be formed simultaneously in a same process, but are not limited thereto. The third wide light emitting layer ELW3 and the third narrow light emitting layer ELN3 may be formed directly on a same layer and may be formed simultaneously in a same process, but are not limited thereto.

Referring to FIG. 13, then, the electron transport portion ETU and the cathode electrode CE are provided or formed on the light emitting layers ELW1, ELW2, ELW3, ELN1, ELN2, and ELN3. The electron transport portion ETU may be entirely formed on the wide pixels PW1, PW2, and PW3 and the narrow pixels PN1, PN2, and PN3. The cathode electrode CE may be entirely formed on the wide pixels PW1, PW2, and PW3 and the narrow pixels PN1, PN2, and PN3.

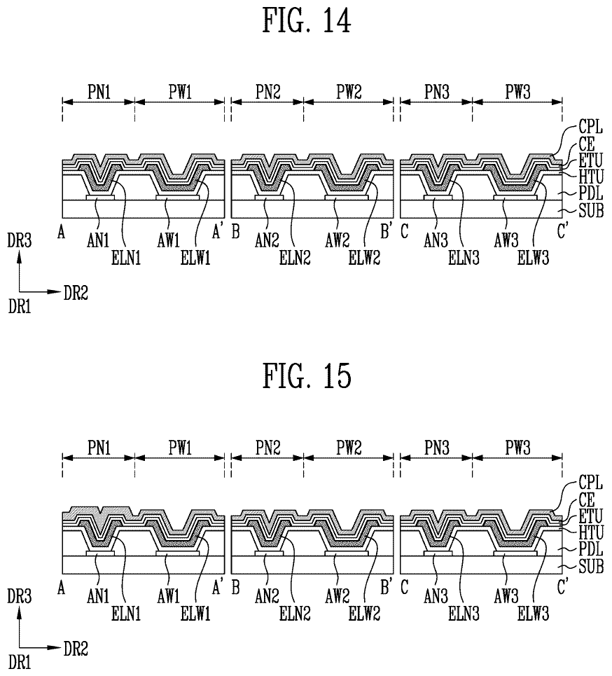

Referring to FIG. 14 and FIG. 15, then, the capping layer CPL may be provided or formed on the cathode electrode CE. First, as shown in FIG. 14, the capping layer CPL may be entirely deposited on the wide pixels PW1, PW2, and PW3 and the narrow pixels PN1, PN2, and PN3. In this case, the capping layer CPL may be formed to have a uniform thickness in the wide pixels PW1, PW2, and PW3 and the narrow pixels PN1, PN2, and PN3.

Subsequently, as shown in FIG. 15, the capping layer CPL may be additionally deposited on the narrow pixels PN1, PN2, and PN3, for example, the first narrow pixel PN1. Accordingly, the thickness of the capping layer CPL of the first narrow pixel PN1 in the third direction DR3 may be formed to be relatively great. As described above, by adjusting the thickness of the capping layer CPL, the light efficiency of the narrow pixels PN1, PN2, and PN3 may be improved, power consumption in the private mode may be improved, and degradation may be minimized to improve reliability.

Subsequently, as described above with reference to FIG. 6, the encapsulation layer TFE, the sensing layer SL, the light blocking layers BM1, BM2, and BM3, the overcoat layers OC1, OC2, and/or the polarizing layer POL may be formed on the capping layer CPL to complete the display device.

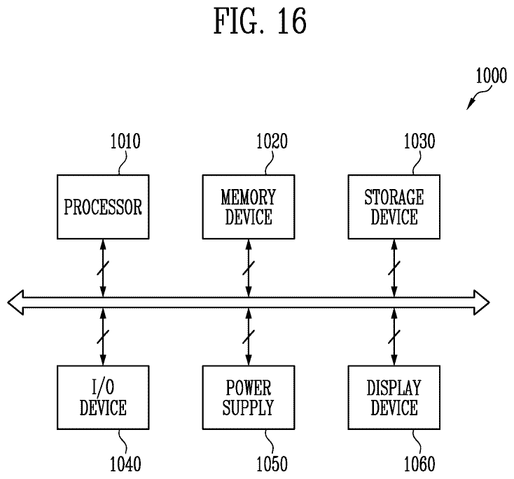

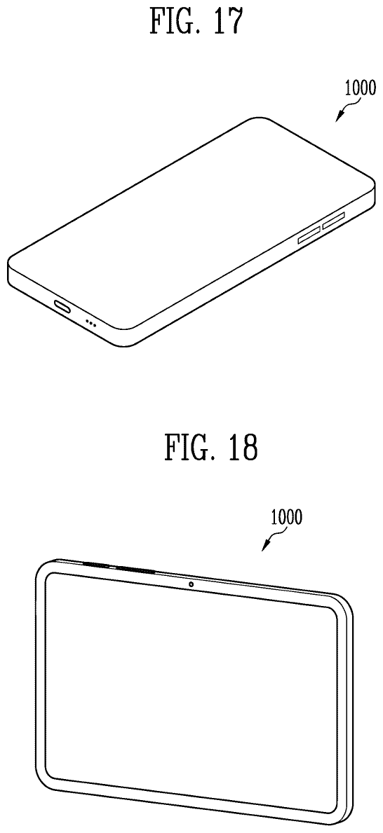

FIG. 16 is a schematic block diagram illustrating an electronic device 1000 including a display device in accordance with an embodiment. FIG. 17 is a schematic diagram illustrating an example where the electronic device 1000 of FIG. 16 is a smartphone. FIG. 18 is a schematic diagram illustrating an example where the electronic device 1000 of FIG. 16 is a tablet computer.

Referring to FIGS. 16 to 18, the electronic device 1000 may include a processor 1010, a memory device 1020, a storage device 1030, an input/output (I/O) device 1040, a power supply 1050, and a display device 1060. The display device 1060 may be the display device of FIG. 1. The electronic device 1000 may further include various ports for communication with a video card, a sound card, a memory card, a USB device, or other systems. In an embodiment, as illustrated in FIG. 17, the electronic device 1000 may be a smartphone. In an embodiment, as illustrated in FIG. 18, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a first narrow pixel and a first wide pixel;
a first electrode on the substrate;
a light emitting layer on the first electrode;
a second electrode on the light emitting layer;
an encapsulation layer on the second electrode; and
a capping layer between the second electrode and the encapsulation layer,
wherein a thickness of the capping layer of the first narrow pixel is greater than a thickness of the capping layer of the first wide pixel.

2. The display device of claim 1, wherein
each of the first narrow pixel and the first wide pixel emits light of a first color.

3. The display device of claim 1, wherein
the first wide pixel emits light in a normal mode, and
the first narrow pixel emits light in a private mode.

4. The display device of claim 1, wherein
a thickness of the light emitting layer of the first narrow pixel is less than a thickness of the light emitting layer of the first wide pixel.

5. The display device of claim 1, wherein
the substrate further includes a second narrow pixel and a second wide pixel, and
a thickness of the capping layer of the second narrow pixel is the same as a thickness of the capping layer of the second wide pixel.

6. The display device of claim 5, wherein
each of the second narrow pixel and the second wide pixel emits light of a second color.

7. The display device of claim 5, wherein
a thickness of the capping layer of the first narrow pixel is greater than a thickness of the capping layer of the second narrow pixel.

8. The display device of claim 1, wherein
the substrate further includes a third narrow pixel and a third wide pixel, and
a thickness of the capping layer of the third narrow pixel is the same as a thickness of the capping layer of the third wide pixel.

9. The display device of claim 8, wherein
each of the third narrow pixel and the third wide pixel emits light of a third color.

10. The display device of claim 8, wherein
a thickness of the capping layer of the first narrow pixel is less than a thickness of the capping layer of the third narrow pixel.

11. The display device of claim 1, wherein
the substrate further includes a second narrow pixel and a second wide pixel, and
a thickness of the capping layer of the second narrow pixel is greater than a thickness of the capping layer of the second wide pixel.

12. The display device of claim 11, wherein
a thickness of the capping layer of the first narrow pixel is the same as a thickness of the capping layer of the second narrow pixel.

13. The display device of claim 11, wherein
a thickness of the capping layer of the first narrow pixel is greater than a thickness of the capping layer of the second narrow pixel.

14. The display device of claim 1, further comprising
a first light blocking layer on the encapsulation layer.

15. The display device of claim 14, wherein
the first light blocking layer is provided with a first opening overlapping the first narrow pixel and a second opening overlapping the first wide pixel.

16. The display device of claim 15, wherein
a width of the first opening in a first direction is less than a width of the second opening in the first direction.

17. The display device of claim 14, further comprising
a second light blocking layer on the first light blocking layer.

18. The display device of claim 17, further comprising
a third light blocking layer on the second light blocking layer.

19. The display device of claim 18, wherein
the first to third light blocking layers overlap each other.

20. The display device of claim 18, further comprising
a polarizing layer on the second light blocking layer.

21. An electronic device comprising:
a processor to provide input image data; and
a display device to display an image based on the input image data, the display device including sub-pixel areas,
wherein the display device comprises:
a substrate including a first narrow pixel and a first wide pixel;
a first electrode on the substrate;
a light emitting layer on the first electrode;
a second electrode on the light emitting layer;
an encapsulation layer on the second electrode; and
a capping layer between the second electrode and the encapsulation layer,
wherein a thickness of the capping layer of the first narrow pixel is greater than a thickness of the capping layer of the first wide pixel.
